(19) United States
(12) Patent Application Publication
(10) Pub. No.: US 2025/0105601 A1
(43) Pub. Date: Mar. 27, 2025

(54) SHIELD RING INCLUDED IN SPACER FOR GAS INSULATION SWITCHGEAR HAVING ELECTRONIC TRANSFORMER EMBEDDED THEREIN

(71) Applicant: TAI HAN ELECTRIC WIRE CO., LTD., Anyang-si, Gyeonggi-do (KR)

(72) Inventors: Daehoon KIM, Seoul (KR); Kisang KIM, Seoul (KR); Jaehyuk SONG, Dangjin-si, Chungcheongnam-do (KR); Dongsuk HONG, Anyang-si, Gyeonggi-do (KR); Hyunjoo KIM, Dangjin-si, Chungcheongnam-do (KR)

(21) Appl. No.: 18/713,569

(22) PCT Filed: Nov. 22, 2022
(86) PCT No.: PCT/KR2022/018462

§ 371 Date: Dec. 13, 2024

(30) Foreign Application Priority Data
Nov. 26, 2021 (KR) 10-10210165769

(51) Int. Cl. H02B 13/035

(52) U.S. Cl. CPC H02B 13/0356

(57) ABSTRACT

A shield ring according to the present invention includes: a first sensor fastening unit having a ring shape having a predetermined thickness; a second sensor fastening unit spaced a predetermined distance apart from a first sensor unit and having a ring shape having a predetermined thickness; a vertical support unit configured to maintain a separation distance of the first sensor fastening unit and a second sensor unit; and a connection support unit which protrudes from the first sensor fastening unit and the second sensor unit and is connected to an outer flange. A shied ring according to the present invention can enhance a binding force with the outer flange to prevent deflection or rotation and can considerably improve load carrying performance.

### TECHNICAL FIELD

The present invention relates to a shield ring for installing a voltage/current sensor for a measurement device, and more specifically, to a shield ring included in a spacer for a gas insulation switchgear having an electronic transformer embedded therein.

### BACKGROUND ART

A spacer for a gas insulation switchgear, which is an insulation component that supports a conductor in the gas insulation switchgear and sets an insulation section, corresponds to a key component that requires sufficient resistance against physical and insulation destruction caused by mechanical stress, such as durability against a high electric-field and heat resistance of an insulating material.

In recent years, as a demand for increase in voltage and precision in current and voltage measurement increases, interest in transformer (CT/VT) that is a high-voltage and high-current measurement device increases. Although the transformer including an iron core and a winding wire has been used so far, the transformer has a disadvantage of: requiring a wide occupied area, i.e., a transformer in a 170 kV class has a length of about ⅙ of that of the entire gas insulating switchgear (GIS); and having a great measurement error on current above a certain limit caused by magnetic saturation characteristics of a magnetic material particularly because the iron core is made of a magnetic material.

In recent years, advanced overseas companies are developing an electronic transformer that does not use an iron core to release the transformer into a market, and developing an electronic transformer in which a Rogowski coil and an electric-field probe are embedded in a spacer. Unlike a typical iron core-type transformer, an electronic transformer for a high-voltage switchgear is made of a solid insulating material to satisfy all conditions of measurement accuracy and high reliability.

FIG. 1 is a view illustrating a typical electronic transformer for a high-voltage switchgear. A typical electronic transformer measures a bus voltage according to the principle of capacitive partial pressure by using an electronic ring and a bus current by using a Rogowskii coil. Here, the electronic ring for bus voltage measurement is made of a cylindrical conductor.

According to the related art, deflection or rotation may occur during molding a main insulating material (epoxy), which causes an imbalance in insulation distance between a central conductor and a shield ring. Here, electric-field distortion may occur, or insulation breakdown may occur under a stressful condition. The shield ring in the related art has a cylindrical shape, and there is a problem in that an interface between the shield ring and the epoxy acts as a weak portion when a load is applied to a finished spacer product in a vertical direction.

### DISCLOSURE OF THE INVENTION

### Technical Problem

The present invention provides a shield ring capable of preventing deflection or rotation by improving a binding force with an outer flange and having a considerably improved load carrying performance.

### Technical Solution

Embodiments of the present invention provide a shielding ring including: a first sensor fastening unit having a ring shape having a predetermined width; a second sensor fastening unit spaced a predetermined distance from the first sensor fastening unit and having a ring shape having a predetermined width; a vertical support unit configured to maintain a separation distance between the first sensor fastening unit and the second sensor fastening unit; and a connection support unit that protrudes from the first sensor fastening unit and the second sensor fastening unit and connected to an outer flange.

In an embodiment, the connection support unit may be a member having a ‘⊏’-shape having one end connected to the first sensor fastening unit and the other end connected to the second sensor fastening unit.

In an embodiment, the vertical support unit may maintain the separation distance of 5 mm.

In an embodiment, the vertical support unit and the connection support unit may be arranged on areas that are opposed by 180°, respectively.

In an embodiment, a conductor of a gas insulation switchgear may be disposed at a center of the ring-shaped first and second sensor fastening units.

In an embodiment, a voltage sensor may be connected to the first sensor fastening unit, and a current sensor is connected to the second sensor fastening unit.

In an embodiment, each of the first sensor fastening unit and the second sensor fastening unit may include at least one stepped portion in a direction of the width.

In an embodiment, the shield ring may be made of aluminum.

### Advantageous Effects

The shied ring according to the present invention may enhance the binding force with the outer flange to prevent the deflection or rotation and considerably improve the load carrying performance.

### BRIEF DESCRIPTION OF THE DRAWINGS

FIG. 1 is a view illustrating a typical electronic transformer for a high-voltage switchgear.

FIG. 2 is a perspective view of a shield ring according to the present invention.

FIG. 3 is a side view of the shield ring according to the present invention.

FIG. 4 is a view illustrating a coupling method between the shield ring and a sensor according to the present invention.

FIG. 5 is a view illustrating a state in which the shield ring is coupled with an outer flange according to the present invention.

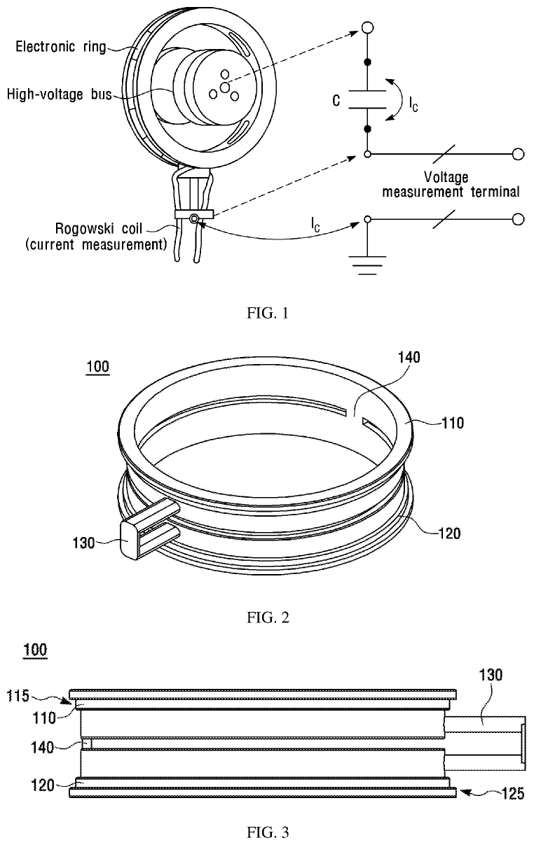

### MODE FOR CARRYING OUT THE INVENTION

The present invention will now be described more fully with reference to the accompanying drawings, in which exemplary embodiments of the invention are shown. These embodiments are provided so that this disclosure will be thorough and complete, and will fully convey the concept of the invention to those skilled in the art. The invention may, however, be embodied in many different forms and should not be construed as being limited to the embodiments set forth herein. Therefore, it will be understood that the embodiments disclosed in this specification includes some variations without limitations to the shapes as illustrated in the figures. Also, the position or the arrangement of each component in the embodiment may be varied without departing form the spirit or scope of the invention. The preferred embodiments should be considered in descriptive sense only and not for purposes of limitation. Therefore, the scope of the invention is defined not by the detailed description of the invention but by the appended claims, and all differences within the scope will be construed as being included in the present invention. In the drawings, like reference numerals refer to like elements throughout.

Hereinafter, the present invention will be described in detail with reference to the accompanying drawings.

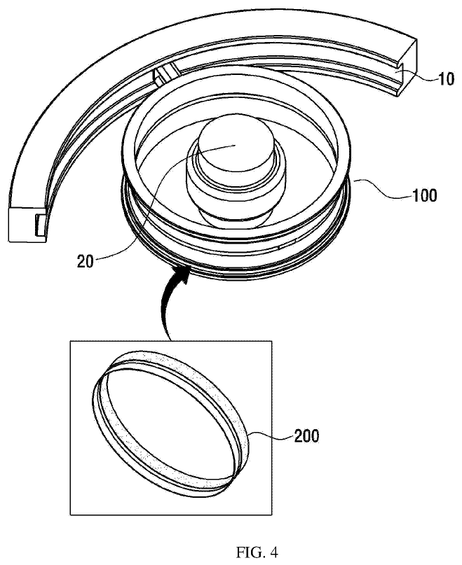

FIG. 2 is a perspective view of a shield ring according to the present invention, and FIG. 3 is a side view of the shield ring according to the present invention. As illustrated in FIGS. 2 and 3, a shield ring 100 according to the present invention includes a first sensor fastening unit 110, a second sensor fastening unit 120, a connection support unit 130, and a vertical support unit 140.

Each of the first sensor fastening unit 110 and the second sensor fastening unit 120 has a ring shape (or cylindrical shape) having a predetermined width. Each of the first sensor fastening unit 110 and the second sensor fastening unit 120 may have a width that is appropriate for a sensor (a current sensor or a voltage sensor) connected thereto to be arranged.

On the other hand, the first sensor fastening unit 110 and the second sensor fastening unit 120 are spaced a predetermined distance from each other. That is, the shield ring according to the present invention has a separation-type structure including upper and lower parts to apply a voltage sensor and a current sensor. Here, a separation distance for excellent insulation performance between a conductor and the shield ring 100 is about 1 mm to 10 mm, preferably about 5 mm, and this separation distance allows an epoxy mold to be smoothly formed.

On the other hand, although each of the first sensor fastening unit 110 and the second sensor fastening unit 120 may be made of aluminum having a coefficient of thermal expansion similar to that of epoxy, which is a main insulating material, the embodiment of the present invention is not limited thereto.

Each of the first sensor fastening unit 110 and the second sensor fastening unit 120 includes at least one stepped portion 115 or 125 in a width direction thereof. That is, as illustrated in FIG. 3, the first sensor fastening unit 110 may have the stepped portion 115 having an outer radius that gradually increases in a direction away from the second sensor fastening unit 120, and the second sensor fastening unit 120 may have the stepped portion 125 having an outer radius that gradually increases in a direction away from the first sensor fastening unit 110. Although the stepped portion having two steps is illustrated in FIG. 3, the stepped portion may have one step or three or more steps in another embodiment.

The stepped portions 115 and 125 prevent an end in the width direction of the sensor fastening units 110 and 120 from acting as a weak interface portion between the shield ring 100 and the epoxy when a load is applied in a vertical direction.

The separation distance between the first sensor fastening unit 110 and the second sensor fastening unit 120 is maintained by the vertical support unit 140. That is, the vertical support unit 140 maintains the predetermined separation distance by connecting partial areas of the first sensor fastening unit 110 and the second sensor fastening unit 120 to each other.

The connection support unit 130 protrudes from the first sensor fastening unit 110 and the second sensor fastening unit 120 and is connected to the outer flange. The connection support unit 130 may be a member having a ‘⊏’-shape having one end connected to the first sensor fastening unit and the other end connected to the second sensor fastening unit.

The connection support unit 10 and the vertical support unit 140 may be disposed opposed to each other. That is, the vertical support unit 140 and the connection support unit 130 may be disposed on areas that are opposed by 180° based on a center point between the first sensor fastening unit 110 and the second sensor fastening unit 120, which is expressed as a circle. Each of the vertical support unit 140 and the connection support unit 130 may be made of aluminum as same as the first sensor fastening unit 110 and the second sensor fastening unit 120, but may be made of other materials.

The shield ring 100 according to the present invention includes two support units of the connection support unit 130 and the vertical support unit 140 to strengthen a binding force with the outer flange and increases a contact area between the shield ring 100 and the outer flange through the connection support unit 130 to prevent deflection or rotation in an epoxy molding process.

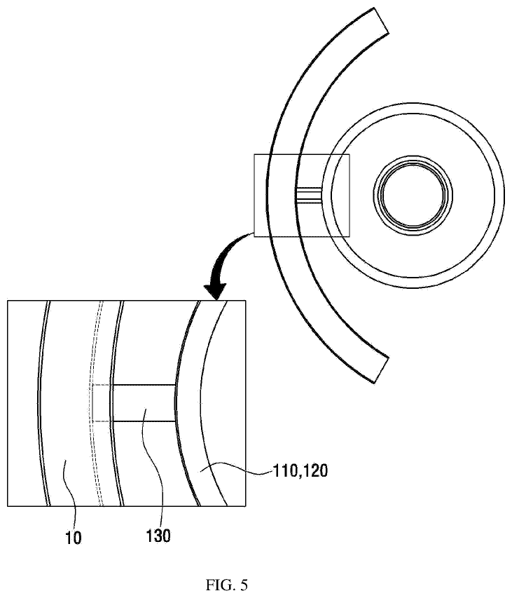

FIG. 4 is a view illustrating a coupling method between the shield ring and a sensor according to the present invention. As illustrated in FIG. 4, a sensor 200 that is a longitudinal sensor (band-shape, ring-shape, etc.) having a predetermined width may be a voltage sensor or a current sensor. Also, the current sensor may be coupled along an outer circumferential surface of the first sensor fastening unit 110, and the voltage sensor may be coupled along an outer circumferential surface of the second sensor fastening unit 120. A width occupied by the voltage sensor may be equal to or less than that of the first sensor fastening unit 110. Likewise, a width occupied by the current sensor may be equal to or less than that of the second sensor fastening unit 120.

A conductor 20 of a gas insulation switchgear may pass through a center of each of the first sensor fastening unit 110 and the second sensor fastening unit 120, and voltage sensing and current sensing may be performed by the voltage sensor and the current sensor, which are coupled to the first sensor fastening unit 110 and the second sensor fastening unit 120, respectively.

FIG. 5 is a view illustrating a state in which the shield ring is coupled with the outer flange according to the present invention.

The connection support unit 130 that connects the first sensor fastening unit 110 and the second sensor fastening unit 120 is inserted and fastened to the outer flange 10. When the connection support unit 130 having the ‘⊏’-shape includes a first connection part having one end connected to the first sensor fastening unit 110, a second connection part having one end connected to the second sensor fastening unit 120, and a bent part that connects the other end of the first connection part and the other end of the second connection part, the bent part may be inserted and fixed to the outer flange 10.

As the shield ring 100 is fastened to the outer flange 10 in a method illustrated in FIG. 5, rotation may be prevented during epoxy molding for forming a spacer. Also, as a length and an area of the bent part are adjusted, a contact area of the outer flange 10 may increase to effectively prevent deflection caused by a load.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### DESCRIPTION OF THE SYMBOLS

100: Shield ring
110: First sensor fastening unit
120: Second sensor fastening unit
130: Connection support unit
140: Vertical support unit

1. A shielding ring comprising:
a first sensor fastening unit having a ring shape having a predetermined width;
a second sensor fastening unit spaced a predetermined distance from the first sensor fastening unit and having a ring shape having a predetermined width;
a vertical support unit configured to maintain a separation distance between the first sensor fastening unit and the second sensor fastening unit; and
a connection support unit that protrudes from the first sensor fastening unit and the second sensor fastening unit and connected to an outer flange.

2. The shielding ring of claim 1, wherein the connection support unit is a member having a ‘⊏’-shape having one end connected to the first sensor fastening unit and the other end connected to the second sensor fastening unit.

3. The shielding ring of claim 1, wherein the vertical support unit maintains the separation distance of 5 mm.

4. The shielding ring of claim 1, wherein the vertical support unit and the connection support unit are arranged on areas that are opposed by 180°, respectively.

5. The shielding ring of claim 1, wherein a conductor of a gas insulation switchgear is disposed at a center of the ring-shaped first and second sensor fastening units.

6. The shielding ring of claim 1, wherein a voltage sensor is connected to the first sensor fastening unit, and a current sensor is connected to the second sensor fastening unit.

7. The shielding ring of claim 1, wherein each of the first sensor fastening unit and the second sensor fastening unit comprises at least one stepped portion in a direction of the width.

8. The shielding ring of claim 1, wherein the shield ring is made of aluminum.
